(19) United States
(12) Patent Application Publication
(10) Pub. No.: US 2020/0279912 A1
(43) Pub. Date: Sep. 3, 2020

(54) SUPER JUNCTION SEMICONDUCTOR DEVICE AND METHOD OF MANUFACTURING THE SAME

(71) Applicant: DB Hitek Co., Ltd., Seoul (KR)

(72) Inventors: Tae Young Joung, Seoul (KR); Choul Joo Ko, Seongnam-si (KR); Myoung Bum Pyan, Incheon (KR); Young Seok Kim, Seongnam-si (KR); Ung Bi Son, Bucheon-si (KR); Myung Hoon Lim, Bucheon-si (KR); Jae Hyun Lee, Seoul (KR)

(21) Appl. No.: 16/804,801

(22) Filed: Feb. 28, 2020

(30) Foreign Application Priority Data
Feb. 28, 2019 (KR) 10-2019-0024416

(51) Int. Cl. H01L 29/06; H01L 29/78

(52) U.S. Cl. CPC H01L 29/0634; H01L 29/0692; H01L 29/7827

(57) ABSTRACT

A super junction semiconductor device includes a substrate of a first conductive type, the substrate having an active region, a peripheral region and a transition region, an epitaxial layer formed on the substrate, the epitaxial layer having the first conductive type, a plurality of pillars extending from the substrate through the epitaxial layer in a vertical direction, a gate electrode structure formed in the active region and on the epitaxial layer, a gate pad structure formed in the transition region and over the epitaxial layer, and a reverse recovery layer interposed between the gate pad structure and the epitaxial layer, the reverse recovery layer being configured to disperse a reverse recovery current at the gate pad structure.

### CROSS-REFERENCE TO RELATED APPLICATION

This application claims priority to Korean Patent Application No. 10-2019-0024416, filed on Feb. 28, 2019 and all the benefits accruing therefrom under 35 U.S.C. § 119, the contents of which are incorporated by reference in their entirety.

### TECHNICAL FIELD

The present disclosure relates to a super junction semiconductor device and a method of manufacturing the same, and more particularly, to a super junction semiconductor device including a metal oxide semiconductor field effect transistor (hereinafter, referred as “MOSFET”) and a method of manufacturing the super junction semiconductor device.

### BACKGROUND

Generally, a semiconductor device having a super junction structure has been widely used to improve a trade-off relation between forward characteristics and reverse characteristics related to a breakdown voltage in a power semiconductor device.

According to the prior art, a super junction semiconductor device includes a plurality of N-typed pillars and a plurality of P-typed pillars alternatively arranged and spaced apart from one another, a P-body region, a gate electrode structure and a termination ring entirely surrounding an active region. Thus, the super junction semiconductor device has a relatively low on-resistance such that the super junction semiconductor device may have a relatively small size. Accordingly, the super junction semiconductor device may have a relatively low capacitance to have an improved switching property.

However, a parasitic P-body diode may occur between the P-body region and the N-typed pillars of the super junction semiconductor device. When the P-body diode is switched from an on-state to an off-state, a reverse recovery phenomena may occur. When the reverse recovery generates, minority carriers are removed in the P-body diode to generate a reverse recovery current (I_{sd}). The reverse recovery (dt/di) may cause a relatively high voltage overshoot due to a floating capacitance. As a result, an increase in a gate-drain charge amount and a current concentration may occur.

In particular, a reverse recovery current may occur under the gate pad being configured to supply power to the gate structure. In this case, the reverse recovery current may be concentrated in a boundary area between the peripheral region where the termination ring is formed and the gate pad. Therefore, a current density increases in the boundary area, and the lattice temperature may increase due to a power loss caused by a relatively high resistance. As a result, a burn-in phenomenon may occur at the boundary area adjacent to the gate pad and the termination ring.

### SUMMARY

The example embodiments of the present disclosure provide a super junction semiconductor device capable of effectively dispersing a reverse recovery current which may occur under a gate pad to suppress a burn-in phenomenon from occurring in a region adjacent the gate pad.

The example embodiments of the present disclosure provide a method of manufacturing a super junction semiconductor device capable of effectively dispersing a reverse recovery current which may occur under a gate pad to suppress a burn-in phenomenon from occurring in a region adjacent the gate pad.

According to an example embodiment of the present disclosure, a super junction semiconductor device includes a substrate of a first conductive type, the substrate having an active region, a peripheral region sul ounding the active region, and a transition region defined between the active region and the peripheral region, an epitaxial layer formed on the substrate, the epitaxial layer having the first conductive type, a plurality of pillars extending from the substrate through the epitaxial layer in a vertical direction, the pillars being spaced apart from each other to be alternatively arranged in a horizontal direction, a gate electrode structure formed in the active region and on the epitaxial layer, the gate electrode structure extending in the horizontal direction to cross the epitaxial layer and the pillars, a gate pad structure formed in the transition region and over the epitaxial layer, the gate pad structure being electrically connected to the gate electrode structure, and a reverse recovery layer interposed between the gate pad structure and the epitaxial layer, the reverse recovery layer being configured to disperse a reverse recovery current generating around the gate pad structure.

In an example embodiment, the reverse recovery layer has an area substantially identical to that of the gate pad structure.

In an example embodiment, the reverse recovery layer entirely overlaps the gate pad structure in a plan view.

In an example embodiment, the reverse recovery layer is provided at a boundary area between the gate pad structure and the transition region.

In an example embodiment, the reverse recovery layer is provided to surround the gate pad structure.

In an example embodiment, the reverse recovery layer is provided under the gate pad structure and along the transition region.

In an example embodiment, the gate electrode structure includes a gate insulating layer extending in the horizontal direction to cross the pillars of the second conductive type, a gate electrode formed on the gate insulating layer, and an insulating interlayer surrounding the gate electrode.

In an example embodiment, a diffusion region may be further interposed between the gate pad structure and the reverse recovery layer.

Here, each of the diffusion region and the reverse recovery layer has the second conductive type. Further, the reverse recovery layer has an ion concentration higher than that of the diffusion region.

According to an example embodiment of the present disclosure, disclosed is a method of manufacturing a super junction semiconductor device. A substrate of a first conductive type is prepared, the substrate having an active region, a peripheral region surrounding the active region, and a transition region defined between the active region and the peripheral region. After an epitaxial layer of the first conductive type is formed on the substrate, pillars of a second conductive type are formed in the epitaxial layer, the pillars extending from the substrate through the epitaxial layer in a vertical direction, and being spaced apart from each other to be alternatively arranged in a horizontal direction. A reverse recovery layer is formed in the transition region and over the epitaxial layer, the reverse recovery layer being configured to disperse a reverse recovery current. A gate electrode structure is formed in the active region and on the epitaxial layer, the gate electrode structure extending in the horizontal direction to cross the epitaxial layer and the pillars. Then, a gate pad structure is formed in the transition region and over the epitaxial layer, the gate pad structure being electrically connected to the gate electrode structure.

In an example embodiment, the reverse recovery layer is formed to have an area substantially identical to that of the gate pad structure.

In an example embodiment, the reverse recovery layer is entirely overlapped with the gate pad structure in a plan view.

In an example embodiment, the reverse recovery layer is formed along a boundary between the gate pad structure and the transition region.

In an example embodiment, the reverse recovery layer is formed to surround the gate pad structure.

In an example embodiment, the reverse recovery layer is formed under the gate pad structure and along the transition region.

In an example embodiment, the reverse recovery layer is formed by performing an ion implanting process.

In an example embodiment, a diffusion region is further formed between the gate pad structure and reverse recovery layer.

In an example embodiment, each of the diffusion region and the reverse recovery layer has the second conductive type.

In an example embodiment, the reverse recovery layer has an ion concentration higher than that of the diffusion region.

According to example embodiments of the super junction semiconductor and the method of manufacturing the super junction semiconductor, the reverse recovery layer is formed around the transition region. Therefore, when the reverse recovery current I_{sd} is concentrated in the boundary area between the transition region TR and the peripheral area PR, the reverse recovery layer is formed in the transition region TR through which the reverse recovery current I_{sd} flows to reduce a resistance value. As a result, the burnt phenomenon may be suppressed from occurring around the boundary area as the lattice temperature is suppressed from increasing.

### BRIEF DESCRIPTION OF THE DRAWINGS

Example embodiments can be understood in more detail from the following description taken in conjunction with the accompanying drawings, in which:

FIG. 1 is a plan view illustrating a super junction semiconductor device in accordance with an example embodiment of the present disclosure;

FIG. 2 is a cross sectional view illustrating an active region AR in FIG. 1;

FIG. 3 is a cross sectional view illustrating a transition region TR in FIG. 1;

FIG. 4 is a cross sectional view illustrating a peripheral region PR in FIG. 1;

FIG. 5 is a plan view illustrating a super junction semiconductor device in accordance with an example embodiment of the present disclosure;

FIG. 6 is a plan view illustrating a super junction semiconductor device in accordance with an example embodiment of the present disclosure; and

FIGS. 7 to 10 are cross sectional views illustrating a method of manufacturing a super junction semiconductor device in accordance with an example embodiment of the present disclosure.

### DETAILED DESCRIPTION OF EMBODIMENTS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a film, a region or a plate is referred to as being ‘on’ another one, it can be directly on the other one, or one or more intervening layers, films, regions, or plates may also be present. By contrast, it will also be understood that when a layer, a film, a region or a plate is referred to as being ‘directly on’ another one, it is directly on the other one, and one or more intervening layers, films, regions or plates do not exist. Also, though terms such as a first, a second, and a third are used to describe various components, compositions, regions, films, and layers in various embodiments of the present disclosure, such elements are not limited to these terms.

Furthermore, and solely for convenience of description, elements may be referred to as “above” or “below” one another. It will be understood that such description refers to the orientation shown in the Figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present disclosure. Accordingly, changes in the shapes of the diagrams, for example, changes in manufacturing techniques and/or allowable errors, are sufficiently expected. The Figures are not necessarily drawn to scale. Accordingly, embodiments of the present disclosure are not described as being limited to specific shapes of areas described with diagrams and include deviations in the shapes and also the areas described with drawings are entirely schematic and their shapes do not represent accurate shapes and also do not limit the scope of the present invention.

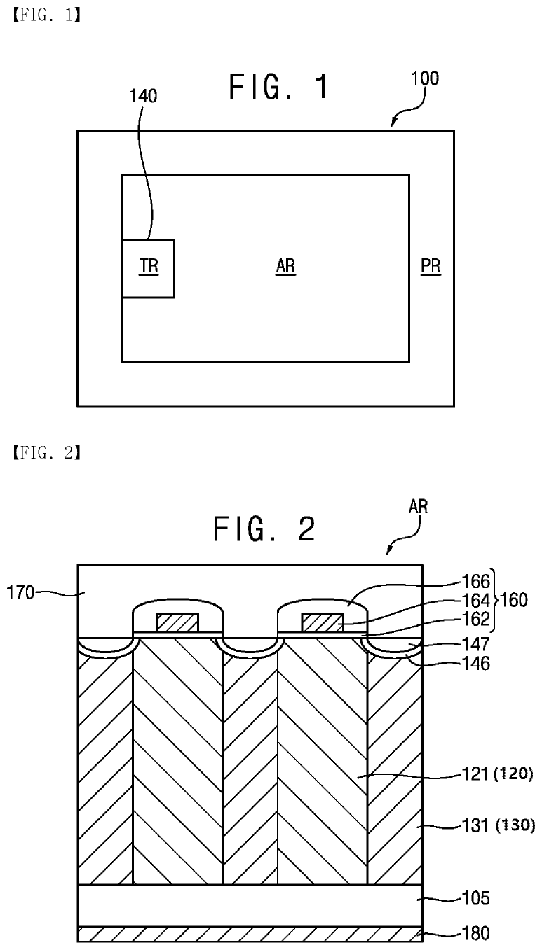

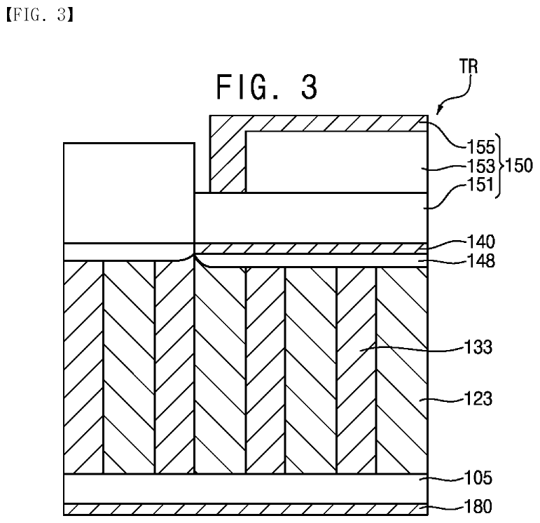

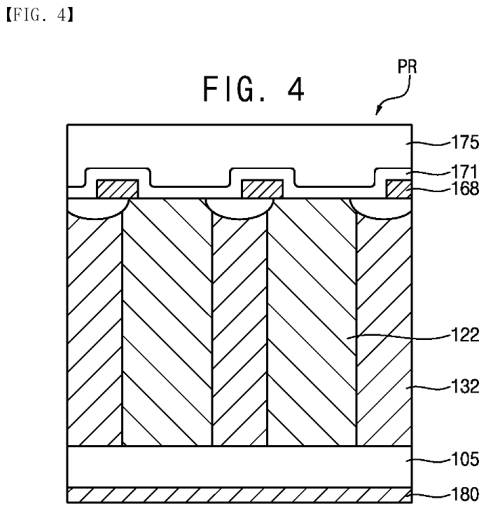

FIG. 1 is a plan view illustrating a super junction semiconductor device in accordance with an example embodiment of the present disclosure. FIG. 2 is a cross sectional view illustrating an active region AR in FIG. 1. FIG. 3 is a cross sectional view illustrating a transition region TR in FIG. 1. FIG. 4 is a cross sectional view illustrating a peripheral region PR in FIG. 1.

Referring to FIGS. 1 to 4, a super junction semiconductor device 100 in accordance with an example embodiment of the present disclosure includes a substrate 105, an epitaxial layer 120, pillars 131, 132 and 133, a gate pad 150, a gate electrode structure 160, a source electrode 170, a drain electrode 180 and a reverse recovery layer 140.

The substrate 105 may include a silicon substrate. The substrate 105 has a first conductive type, for example, a high concentration n⁺ type.

The substrate 105 may be divided into an active region AR, a peripheral region PR and a transition region TR. The active region AR is located at a central area of the semiconductor device. It is in the active region AR that a power MOSFET is formed. The peripheral region PR surrounds the active region AR. Further, the transition region TR is defined as a partial region interposed between the active region AR and the peripheral region PR.

The epitaxial layer 120 is formed on the substrate 105. The epitaxial layer 120 has the first conductive type, for example, a low concentration n″ type. The epitaxial layer 120 may be formed by growing from the substrate 105 through an epitaxial growth process. The epitaxial layer 120 may be formed entirely on the substrate 105 including the active region AR, the peripheral region PR and the transition region TR. That is, the epitaxial layer 120 may include active epitaxial layers 121 positioned in the active region AR, epitaxial layers 122 positioned in the transition region TR and epitaxial layers 123 positioned in the peripheral region PR.

The pillars 130 are provided inside the epitaxial layer 120 to extend in a vertical direction. The pillars 130 may penetrate through the epitaxial layer 120. The pillars 130 have a second conductive type. In the embodiment in which the epitaxial layer 120 has the n-type conductivity, for example, the pillars 131-133 have the p⁻ type conductivity. The pillars 130 may be formed entirely on the substrate 105 including the active region AR, the peripheral region PR and the transition region TR. That is, the pillars 130 may include active pillars 131 positioned in the active region AR, pad pillars 132 positioned in the transition region TR and peripheral pillars 133 positioned in the peripheral region PR.

The pillars 130 are alternatively arranged in a horizontal direction with respect to the surrounding material. That is the pillars 130 are spaced apart from one another by a predetermined distance in the horizontal direction. Accordingly, the pillars 130 and the epitaxial layer 120 are alternatively arranged to one another.

Referring to FIG. 2 again, a P-body region 146 and a high concentration region 147 are positioned on the active pillars 131. The high concentration region 147 is interposed between the P-body region 146 and the active pillars 131. The P-body region 146 may partially surround a lower portion of the high concentration region 147. Since each of the P-body region 146 and the high concentration region 147 has a relatively low resistance, the P-body region 146 and the high concentration region 147 may stably secure an electrical connection between the active pillars 131 and the source electrode 170.

The gate electrode structure 160 is located in the active region AR and on the active epitaxial layers 121. The gate electrode structure 160 extends in the horizontal direction to cross both the active epitaxial layers 121 and the active pillars 131. The gate electrode structure 160 has a stripe shape. When a plurality of the gate electrode structures 160 is provided on the active region AR, the gate electrode structures 160 are spaced apart from each other. In particular, the gate electrode structures 160 may be positioned to cross the active epitaxial layers 121 and each of them may have a hexagonal cross section, adjacent to one another.

Since each of the gate electrode structures 160 has a stripe shape, the gate electrode structures 160 have relatively small areas so that an input capacitance of the super junction semiconductor device 100 can be reduced.

In an example embodiment, each of the gate electrode structures 160 includes a gate insulating layer 162, a gate electrode 164 and a hard mask layer 166.

The gate insulating layer 162 is provided on the active epitaxial layers 121 to cross the active epitaxial layers 121. The gate insulating layer 162 may include an oxide.

The gate electrode 164 is located on the gate insulating layer 162. A width of the gate electrode 164 may be narrower than that of the gate insulating layer 162. For example, the gate electrode 164 includes polysilicon.

The hard mask layer 166 is disposed on the gate electrode 164 so as to surround the gate electrode 164. The hard mask layer 166 electrically isolates the gate electrode 164 and the source electrode 170 from each other. The hard mask layer 166 may include a nitride layer.

In an example embodiment, although not shown, the gate electrode structure 160 may have a trench structure. The gate electrode structure 160 is formed inside of the active epitaxial layers 121 to extend along the vertical direction.

When the gate electrode structure 160 has the trench structure, an interval between the active pillars 131 can be reduced, and the super junction semiconductor device 100 can have improved forward characteristics by enhancing a degree of integration of the super junction semiconductor device 100.

Referring to FIG. 3, the gate pad structure 150 is provided in the transition region TR and on the transition epitaxial layers 123 and the transition pillars 133. The gate pad structure 150 is electrically connected to the gate electrode structure 160. The gate pad structure 150, for example, is electrically connected to the gate electrode 164 included in the gate electrode structure 160.

The gate pad structure 150 may include a field oxide layer 151, an insulating interlayer 153 and a gate pad 155.

The filed oxide layer 151 is positioned in the transition region TR and on the transition epitaxial layers 123 and the transition pillars 133. The field oxide layer 151 may be formed by partially oxidizing the transition epitaxial layers 123 and the transition pillars 133 to electrically isolate the transition region TR from the active region AR.

The insulating interlayer 153 is provided to partially cover the field oxide layer 151. The insulating interlayer 153 electrically isolates the gate pad structure 150 from other electrical devices that may be positioned adjacent to the gate pad structure 150.

The gate pad 155 is disposed on the insulating interlayer 153 and on an exposed portion of the field oxide layer 151. The gate pad 155 is electrically connected to the gate electrode 164 (see FIG. 2) which is provided in the active region AR.

Further, the transition epitaxial layers 123 and the transition pillars 133 are provided in the transition region TR and under the gate pad structure 150.

The reverse recovery layer 140 is disposed under the gate pad structure 150. In addition, the reverse recovery layer 140 may be located in the transition region TR. The reverse recovery layer 140 may be provided to correspond to the transition region TR and may have the same area as the gate pad structure 150.

Alternatively, the reverse recovery layer 140 may be formed along the transition region TR and the peripheral region PR.

The reverse recovery layer 140 may have the second conductive type, for example, P-type conductivity. The reverse recovery layer 140 may be formed through an ion implantation process using a group III element, for example, such as boron, gallium, or indium as an impurity element.

The reverse recovery layer 140 is provided to disperse the reverse recovery current generated from the gate pad structure 150.

When the super junction semiconductor device 100 is switched from an on-state to an off-state, a reverse recovery phenomena may occur. In particular, the reverse recovery phenomena happen at a lower portion of the gate pad structure 150 in the transition region TR such that the reverse recovery current I_{sd} may be concentrated in a boundary area between the transition region TR and the peripheral region PR. In this case, the reverse recovery current I_{sd} may flow through the reverse recovery layer 140 such that the reverse recovery layer 140 formed in the transition region TR may decrease a resistance against the reverse recovery current Isd to suppress a lattice temperature from increasing. As a result, the burnt phenomenon around the boundary area may be suppressed.

Referring again to FIG. 2, the source electrode 170 is formed on the active epitaxial layers 121 to cover the gate electrode structure 160. The source electrode 170 is electrically connected to the high concentration region 147. The drain electrode 180 is formed on a lower surface of the substrate 105.

Referring again to FIG. 3, a diffusion layer 148 may be further provided in the transition region TR and on both the transition pillars 133 and the transition epitaxial layers 123. An end portion of the diffusion region 148, which is defined along the horizontal direction, may be bridged to one of the active pillars 131 positioned in the active region AR. Thus, the diffusion region 148 may connect the transition pillars 133 positioned in the transition region TR to one of the active pillars 131 provided in the active region AR. As a result, the transition pillars 133 may be connected to the source electrode 170 through both the diffusion region 148 and the active pillars 131.

Accordingly, the diffusion region 148 is provided to cross the transition pillars 133 and the transition epitaxial layers 123 in the transition region TR. In this case, the transition region TR may be defined by a width of the diffusion region 148.

The diffusion region 148 may have a doping concentration similar to that of the P-body region 146 provided in the active region AR.

In the meantime, the reverse recovery layer 140 may have the doping concentration higher than that of the diffusion region 148. Accordingly, when the reverse recovery current I_{sd} flows, the reverse recovery layer 140 formed in the transition region TR may effectively reduce the resistance against the reverse recovery current I_{sd}.

Referring to FIG. 4, a field plate electrode 168 is formed in the peripheral region PR. The field plate electrode 168 may have a floating state. Thus, the field plate electrode 168 is also referred to as a dummy electrode herein.

The field plate electrode 168 is disposed on the peripheral epitaxial layer 122 and in the peripheral region PR. The field plate electrode 168 may be made of, for example, a polysilicon material. Meanwhile, an insulating interlayer 171 is provided to cover the field plate electrode 168. In addition, a surface protection layer 175 is formed to cover the insulating interlayer 171.

As described above, the peripheral epitaxial layers 122 and the peripheral pillars 132 extend along the horizontal direction, respectively, in the peripheral region PR. In addition, the peripheral epitaxial layers 122 and the peripheral pillars 132 may be alternately arranged with respect to one another.

As the field plate electrode 168 is provided in the peripheral region PR, the super junction semiconductor device 100 may have an improved breakdown voltage by relaxing electric field concentration and further increasing breakdown voltage.

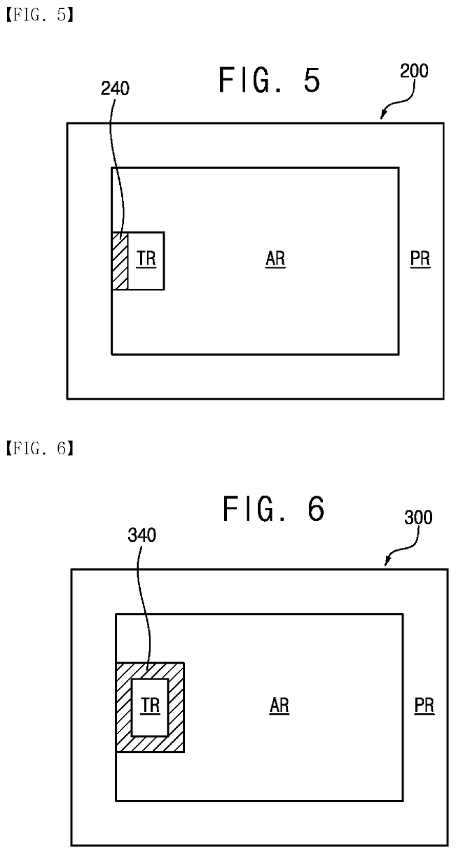

FIG. 5 is a plan view illustrating a super junction semiconductor device in accordance with an example embodiment of the present disclosure.

Referring to FIG. 5, a super junction semiconductor device 200 according to an embodiment of the present invention includes a substrate, an epitaxial layer, pillars, a gate pad structure, a gate electrode structure, a source electrode, and a reverse recovery layer 240. Here, the substrate, the epitaxial layer, the pillars, the gate pad, the gate electrode structure, and the source electrode are substantially the same as the elements described with reference to FIGS. 1 to 4, with reference numbers (when shown) iterated by a factor of 100 from their counterparts in those figures. Thus, the reverse recovery layer 240 will be described in detail.

The reverse recovery layer 240 is selectively formed along a boundary between the transition region TR and the peripheral regions PR. Thus, the reverse recovery layer 240 reduces the resistance against the reverse recovery current I_{sd} when the reverse recovery current I_{sd} flows along the boundary area between the transition region TR and the peripheral region PR. Therefore, the reverse recovery layer 240 may effectively suppress the lattice temperature from increasing. As a result, the burnt phenomena which may occur around the boundary may be suppressed.

FIG. 6 is a plan view illustrating a super junction semiconductor device in accordance with an example embodiment of the present disclosure.

Referring to FIG. 6, a super junction semiconductor device 200 according to an embodiment of the present invention includes a substrate, an epitaxial layer, pillars, a gate pad structure, a gate electrode structure, a source electrode, and a reverse recovery layer 340. Here, the substrate, the epitaxial layer, the pillars, the gate pad, the gate electrode structure, and the source electrode are substantially the same as the elements described with reference to FIGS. 1 to 4, again iterated by a factor of 100 when similar structures are shown again in FIG. 6. Thus, the reverse recovery layer 340 will be described in detail.

The reverse recovery layer 340 is selectively formed to surround the transition region TR. Thus, the reverse recovery layer 340 may reduce the resistance against the reverse recovery current I_{sd} when the reverse recovery current I_{sd} flows along the boundary between the transition region TR and the peripheral region PR. Therefore, the reverse recovery layer 340 may effectively suppress the lattice temperature from increasing. As a result, the burnt phenomena may be suppressed from occurring around the boundary.

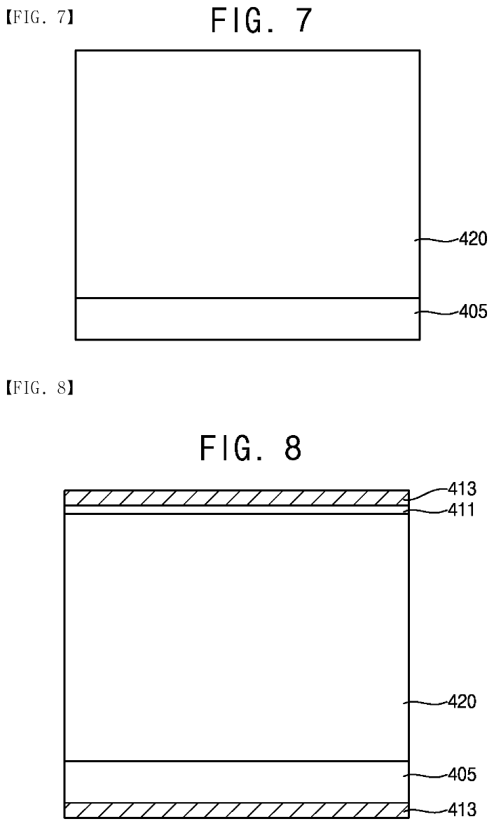

FIGS. 7 to 10 are cross sectional views illustrating a method of manufacturing a super junction semiconductor device in accordance with an example embodiment of the present invention.

Referring to FIG. 7, a cross-sectional view of a semiconductor wafer is shown. In particular, FIG. 7 shows the cross-section of an epitaxial layer 420 of a first conductive type, for example, a low concentration n-type, is formed on a substrate 105 having the first conductive type. The epitaxial layer 120 may be formed by performing an epitaxial growth process against the substrate 105.

Referring to FIG. 8, after a buffer oxide layer 411 is formed on an upper face of the epitaxial layer 420, a polysilicon layer 413 is formed on the buffer oxide layer 411.

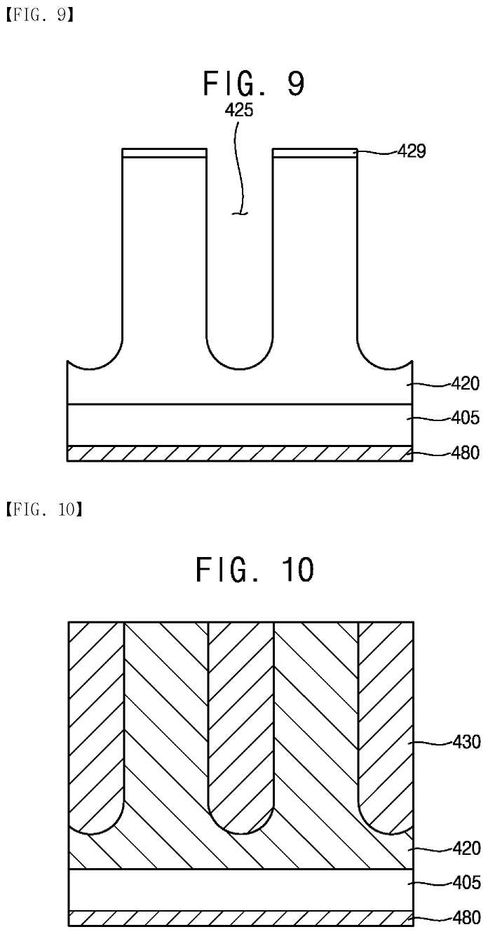

Referring to FIG. 9, after patterning the buffer oxide layer 411 and the polysilicon layer 413 to form a mask pattern on the epitaxial layer 420, an etching process is performed using the mask pattern to form trenches 425 for forming pillars 130 (see FIGS. 2-4) in the epitaxial layer 420. That is, the trenches 145 (see FIG. 2) may be formed by a conventional etch process using the mask pattern 429. Then, the mask pattern is moved from the epitaxial layer 420 by a chemical mechanical polishing (CMP) process.

Referring to FIG. 10, an epitaxial growth process is performed to fill the trenches 425. After performing a post baking process, a CMP process is carried out. As a result, pillars are formed in the trenches 425 of FIG. 9.

Referring again to FIGS. 1 to 4, a first ion implanting process is carried out to form a P-body region 146 in an active region AR and a diffusion layer 148 in a transition regions TR, respectively. A reverse recovery layer 140 is further formed in the diffusion layer 148.

Then, after a field oxidation layer 151 is formed in the transition layer 151 through an oxidation process, a gate electrode structure 160 having a gate oxide layer 162 and a gate polysilicon layer 164 is formed in the active region AR.

An ion implanting process is carried out using the gate electrode structure 160 as a mask to implant ions into the P-body region such that a high concentration region 147 is formed in the active region AR.

An insulating interlayer 153 is formed through a deposition process and a reflow process. After the insulating interlayer 153 and the gate oxide layer 162 are patterned to form contact openings exposing the high concentration region 147.

After, a metal layer filling the contact openings is formed, a source electrode 170 may be connected to the active pillars 131 through the high concentration regions 147.

Meanwhile, an additional process may be performed to form a drain electrode 180 on a rear surface of the substrate 405.

As described above, according to the super junction semiconductor device and the manufacturing method thereof according to the present invention, when the reverse recovery current I_{sd} is concentrated along the boundary between the transition region TR and the peripheral region PR, the reverse recovery layer positioned in the transition region TR may decrease a resistance of the reverse recovery current I_{sd} which flows through the reverse recovery layer. Therefore, since a lattice temperature is suppressed from increasing. a burnt phenomenon may be suppressed from occurring.

Although the super junction semiconductor device has been described with reference to the specific embodiments, they are not limited thereto. Therefore, it will be readily understood by those skilled in the art that various modifications and changes can be made thereto without departing from the spirit and scope of the appended claims.

1. A super junction semiconductor device comprising:
a substrate of a first conductive type, the substrate having an active region, a peripheral region surrounding the active region, and a transition region defined between the active region and the peripheral region;
an epitaxial layer formed on the substrate, the epitaxial layer having the first conductive type;
a plurality of pillars extending from the substrate through the epitaxial layer in a vertical direction, the pillars being spaced apart from one another to be alternatively arranged in a horizontal direction;
a gate electrode structure formed in the active region and on the epitaxial layer, the gate electrode structure extending in the horizontal direction to cross the epitaxial layer and the pillars;
a gate pad structure formed in the transition region and over the epitaxial layer, the gate pad structure being electrically connected to the gate electrode structure; and
a reverse recovery layer interposed between the gate pad structure and the epitaxial layer, the reverse recovery layer being configured to disperse a reverse recovery current at the gate pad structure.

2. The super junction semiconductor device of claim 1, wherein the reverse recovery layer has an area substantially identical to that of the gate pad structure.

3. The super junction semiconductor device of claim 1, wherein the reverse recovery layer entirely overlaps the gate pad structure in a plan view.

4. The super junction semiconductor device of claim 1, wherein the reverse recovery layer is provided at a boundary area between the gate pad structure and the transition region.

5. The super junction semiconductor device of claim 1, wherein the reverse recovery layer covers the gate pad structure.

6. The super junction semiconductor device of claim 1, wherein the reverse recovery layer is provided under the gate pad structure and adjacent the transition region.

7. The super junction semiconductor device of claim 1, wherein the gate electrode structure includes:
a gate insulating layer extending in the horizontal direction to cross the pillars of the second conductive type;
a gate electrode formed on the gate insulating layer; and
an insulating interlayer surrounding the gate electrode.

8. The super junction semiconductor device of claim 1, further comprising a diffusion region interposed between the gate pad structure and the reverse recovery layer.

9. The super junction semiconductor device of claim 8, wherein each of the diffusion region and the reverse recovery layer has the second conductive type.

10. The super junction semiconductor device of claim 8, wherein the reverse recovery layer has an ion concentration higher than that of the diffusion region.

11. A super junction semiconductor device product made by the process of:
preparing a substrate of a first conductive type, the substrate having an active region, a peripheral region surrounding the active region, and a transition region defined between the active region and the peripheral region;
forming an epitaxial layer of the first conductive type on the substrate;
forming pillars of a second conductive type in the epitaxial layer, the pillars extending from the substrate through the epitaxial layer in a vertical direction, and being spaced apart from each other to be alternatively arranged in a horizontal direction;
forming a reverse recovery layer in the transition region and over the epitaxial layer, the reverse recovery layer being configured to disperse a reverse recovery current;
forming a gate electrode structure in the active region and on the epitaxial layer, the gate electrode structure extending in the horizontal direction to cross the epitaxial layer and the pillars; and
forming a gate pad structure in the transition region and over the epitaxial layer, the gate pad structure being electrically connected to the gate electrode structure.

12. The product of claim 11, wherein the reverse recovery layer has an area substantially identical to that of the gate pad structure.

13. The product of claim 11, wherein the reverse recovery layer is entirely overlapped with the gate pad structure in a plan view.

14. The product of claim 11, wherein the reverse recovery layer is formed along a boundary between the gate pad structure and the transition region.

15. The product of claim 11, wherein the reverse recovery layer is formed to surround the gate pad structure.

16. The product of claim 11, wherein the reverse recovery layer is formed under the gate pad structure and adjacent the transition region.

17. The product of claim 11, wherein the reverse recovery layer is formed by performing an ion implanting process.

18. The product of claim 11, wherein the product is made by the process further comprising forming a diffusion region between the gate pad structure and reverse recovery layer.

19. The product of claim 18, wherein each of the diffusion region and the reverse recovery layer has the second conductive type.

20. The product of claim 18, wherein the reverse recovery layer has an ion concentration higher than that of the diffusion region.
